(19) United States
(12) Patent Application Publication
(10) Pub. No.: US 2023/0209776 A1
(43) Pub. Date: Jun. 29, 2023

(54) HEAT DISSIPATION DEVICE AND HEAT DISSIPATION DEVICE ASSEMBLING METHOD

(71) Applicants: CHAMP TECH OPTICAL (FOSHAN) CORPORATION, Foshan (CN); Foxconn Technology Co., Ltd., New Taipei (TW)

(72) Inventors: MENG FU, Foshan (CN); JIN-RONG XIE, Foshan (CN); WEI-DONG CHEN, Foshan (CN)

(21) Appl. No.: 17/668,539

(22) Filed: Feb. 10, 2022

(30) Foreign Application Priority Data
Dec. 28, 2021 (CN) 202111620682.2

(51) Int. Cl. H05K 7/20; F28D 15/02

(52) U.S. Cl. CPC H05K 7/20336; H05K 7/20409; F28D 15/0275; F28D 15/0233

(57) ABSTRACT

A compact heat dissipation device with an improved means of heat dissipation includes a heat conducting plate, a heat dissipating fin, and a plurality of U-shaped heat transferring tubes. The heat conducting plate defines a first through hole. The heat dissipating fin is fixed on the heat conducting plate. A first end of each of the plurality of heat transferring tubes is connected to the heat dissipating fin, a second end of each of the plurality of heat transferring tubes is arranged in the first through hole so as to be side by side with each other, and side surfaces of the second ends are in surface contact. The present disclosure also provides a heat dissipation device assembling method.

### FIELD

The subject matter herein generally relates to a heat dissipation device and a heat dissipation device assembling method.

### BACKGROUND

With the upgrading of CPU chips, a CPU now means higher and higher power consumption and high heat generation. The heat dissipation efficiency of CPU directly affects the performance of CPU. In computer devices, heat dissipating fins are set to dissipate heat generated by a CPU. In order to improve the heat conduction efficiency between the CPU and the heat dissipating fins, a plurality of heat conduction tubes are set between the heat dissipating fins and the CPU, and the heat generated by the CPU is better transmitted to the heat dissipating fins through the heat conduction tubes, so as to improve the heat dissipation efficiency of the CPU. Although the setting of the heat conduction tubes improves the heat dissipation efficiency of the CPU, the heat conduction tubes are circular and are arranged at an interval between the heat conduction tubes. In this way, the conduction path means that there is a single heat conduction direction to the heat dissipating fins, and meeting the heat dissipation demands of the CPU with increasing power consumption is problematic.

### BRIEF DESCRIPTION OF THE DRAWINGS

Implementations of the present technology will now be described, by way of embodiments with reference to the attached figures.

FIG. 1 is an isometric view of a heat dissipation device at a first angle.

FIG. 2 is an isometric view of the heat dissipation device in FIG. 1 at a second angle.

FIG. 3 is an exploded view of the heat dissipation device in FIG. 1.

FIG. 4 is similar to FIG. 3, but from another point of view.

FIG. 5 is a flowchart of a heat dissipation device assembling method.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better show details and features of the present disclosure. The disclosure is by way of embodiments and not by way of limitation in the figures of the accompanying drawings, in which like references indicate similar elements. It should be noted that references to “an” or “one” embodiment in this disclosure are not necessarily to the same embodiment, and such references mean “at least one.”

Several definitions that apply throughout this disclosure will now be presented.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series, and the like. References to “a plurality of” and “a number of” mean “at least two”.

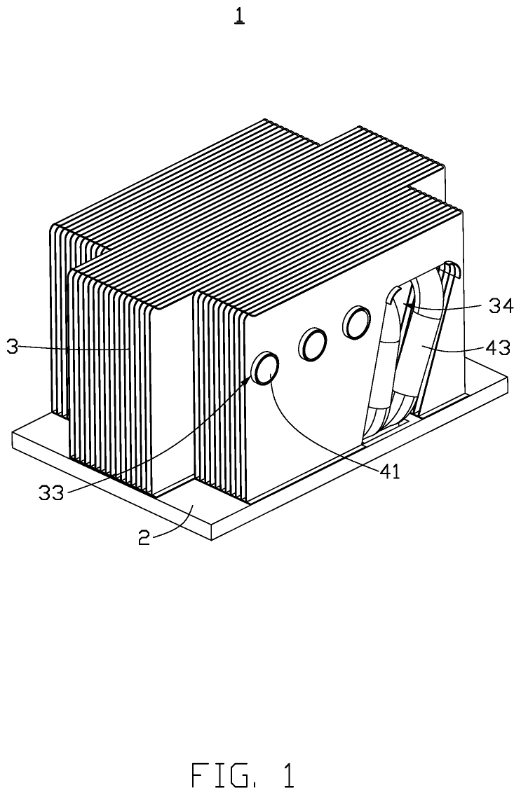

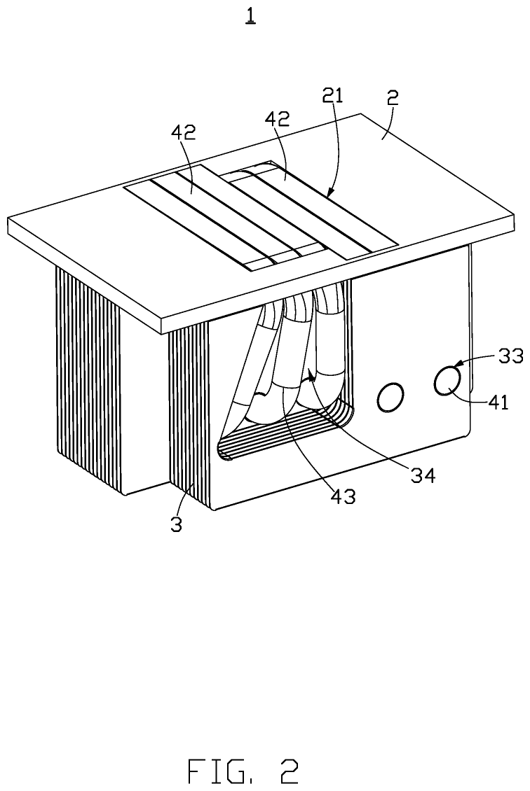

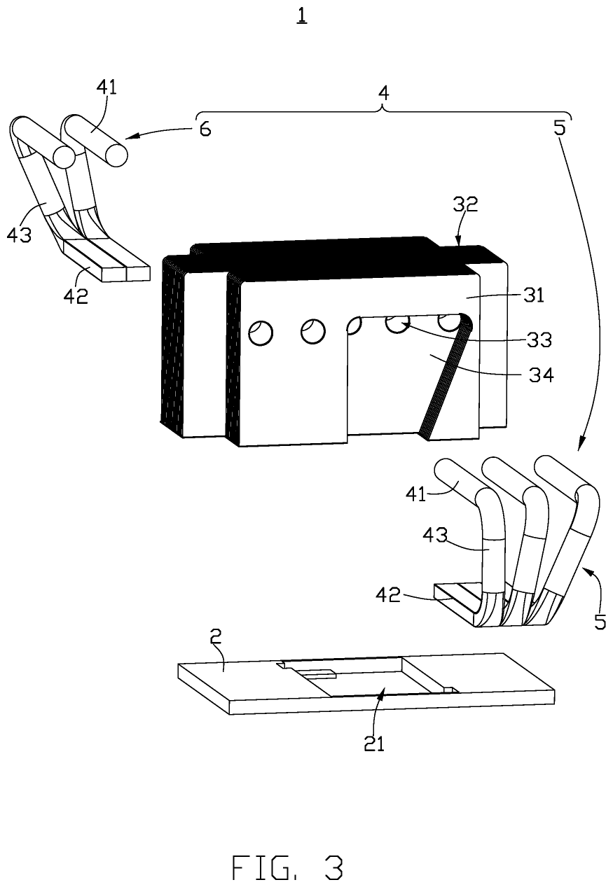

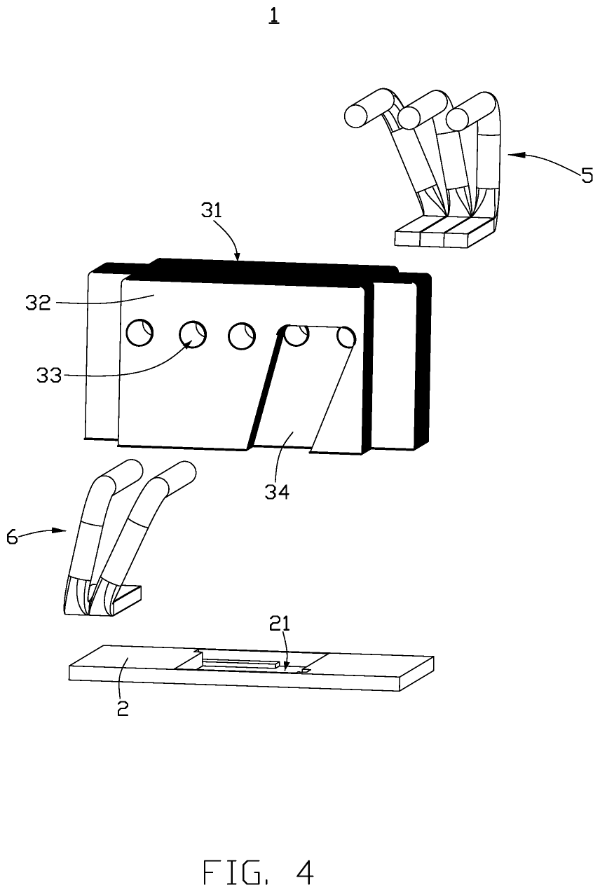

Referring to FIGS. 1 to 4, the present disclosure provides a heat dissipation device 1 for installation on an electronic device, such as a CPU, to dissipate heat generated by the electronic device. The heat dissipation device 1 includes a heat conducting plate 2, a heat dissipating fin 3, and a plurality of U-shaped heat transferring tubes 4. The heat conducting plate 2 is connected with electronic elements and defines a first through hole 21. The heat conducting plate 2 can be an aluminum plate. The heat dissipating fin 3 is fixed on the heat conducting plate 2. Each of the heat transferring tubes 4 includes a first end 41 and a second end 42 opposite to each other. The first ends 41 of the heat transferring tubes 4 are connected to the heat dissipating fin 3, the second ends 42 of the heat transferring tubes 4 are arranged in the first through hole 21 side by side, and side surfaces of the second ends 42 of at least two heat transferring tubes 4 are in surface contact.

In an embodiment, the first end 41 of the heat transferring tube 4 is a cylinder. It can be understood that the first end 41 of the heat transferring tube 4 can also be other shape, such as a cuboid. The second end 42 of the heat transferring tube 4 is a cuboid, and a side of the second end 42 away from the heat dissipating fin 3 is flush with a side of the heat conducting plate 2 away from the heat dissipating fin 3. In this way, when the heat conducting plate 2 is fixedly connected to the electronic element, the heat dissipation device 1 can have greater contact with the surface of the electronic element, so as to improve the heat dissipation performance. It can be understood that the second end 42 of the heat transferring tube 4 can also be other shape, such as a hexahedron.

The heat dissipating fin 3 includes a first side 31 and a second side 32 opposite to each other, and defines a plurality of second through holes 33 penetrating the first side 31 and the second side 32. The second through hole 33 is used for the first end 41 to pass through the heat dissipating fin 3. The shape of the second through hole 33 is circular matching the first end 41. The heat transferring tube 4 contacts the inner wall of the second through hole 33, so that the heat transferring tube 4 can more easily transfer heat to the heat dissipating fin 3. The first side 31 and the second side 32 define two holding grooves 34. The heat transferring tube 4 includes a connecting part 43 connecting the first end 41 and the second end 42, and the connecting part 43 is received in the holding groove 34.

The heat transferring tubes 4 are divided into a first group 5 and a second group 6. Each of the first group 5 and the second group 6 includes a plurality of the heat transferring tubes 4. In some embodiments, the first group of heat transferring tubes 5 includes three heat transferring tubes 4, and the second group of heat transferring tubes 6 includes two heat transferring tubes 4. The first ends 41 of the heat transferring tubes 4 in each of the first group 5 and the second group 6 are arranged at intervals. The first end 41 of each heat transferring tube 4 in the first group of heat transferring tubes 5 is placed in the second through hole 33 and passes through the heat dissipating fin 3 from the first side 31 to the second side 32. The first end 41 of each heat transferring tube 4 in the second group of heat transferring tubes 6 is placed in the second through hole 33 and passes through the heat dissipating fin 3 from the second side 32 to the first side 31. The second ends 42 of the heat transferring tubes 4 in each of the first group 5 and the second group 6 are arranged in the first through hole 21 side by side, every two adjacent heat transferring tubes 4 are in surface contact. An outer side of the second end 42 of the first group of heat transferring tubes 5 is in surface contact with an outer side of the second end 42 of the second group of heat transferring tubes 6. In this way, all heat transferring tubes 4 included in the heat dissipation device 1 are arranged side by side and every two adjacent sides are in surface contact, which allows greater and faster transfer of heat between the heat transferring tubes 4, thereby increasing the heat dissipation efficiency.

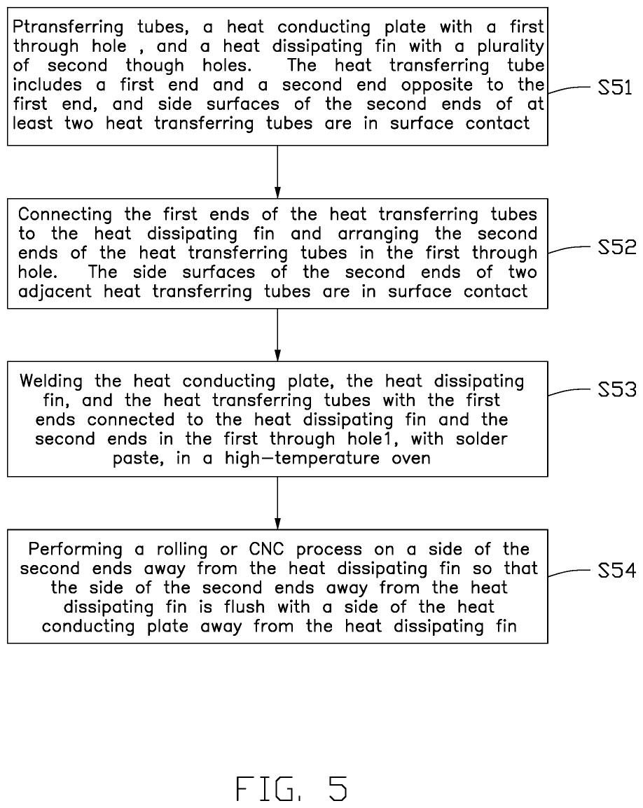

Referring to FIG. 5, the present disclosure also provides a method for assembling a heat dissipation device, which includes the following steps.

Step S51: providing a plurality of U-shaped heat transferring tubes 4, a heat conducting plate 2 with a first through hole 21, and a heat dissipating fin 3 with a plurality of second though holes 33. The heat transferring tube 4 includes a first end 41 and a second end 42 opposite to the first end 41, and side surfaces of the second ends 42 of at least two heat transferring tubes 4 are in surface contact.

Step S52: connecting the first ends 41 of the heat transferring tubes 4 to the heat dissipating fin 3 and arranging the second ends 42 of the heat transferring tubes 4 in the first through hole 21. The side surfaces of two adjacent heat transferring tubes 4 are in surface contact.

Step S53: welding the heat conducting plate 2, the heat dissipating fin 3, and the heat transferring tubes 4 with the first ends 41 connected to the heat dissipating fin 3 and the second ends 42 in the first through hole 21, with solder paste, in a high-temperature oven;

Step S54: performing a rolling or CNC process on a side of the second ends 42 away from the heat dissipating fin 3 so that the side of the second ends 42 away from the heat dissipating fin 3 is flush with a side of the heat conducting plate 2 away from the heat dissipating fin 3.

It can be understood that in some embodiments, the above-described heat dissipation device assembling method includes steps S51-S53 without step S54.

The heat dissipation device 1 and the heat dissipation device assembling method bring the side surfaces of the second ends 42 of at least two heat transferring tubes 4 into surface contact. When dissipating heat generated by the electronic element, the heat is not only transferred from the electronic element towards the heat dissipating fin 3, but is also transferred between the heat transferring tubes 4. In this way, the heat is transferred and dissipated in multiple directions, thus the heat can be transferred faster to the heat dissipating fin 3, so as to improve the heat dissipation efficiency, and better meet the heat dissipation requirements of the electronic element such as a CPU. Further, since the side surfaces of the second ends 42 of the at least two heat transferring tubes 4 are in physical contact, installation space is saved compared with the spacing of the heat transferring tubes 4, so as to increase the number of the heat transferring tubes 4 which can be installed on the heat conducting plate 2 of the same size. Since more heat transferring tubes 4 are used to transfer the heat generated by the electronic element to the heat dissipating fin 3, the heat dissipation efficiency is further improved.

The embodiments shown and described above are only examples. Therefore, many commonly-known features and details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will, therefore, be appreciated that the embodiments described above may be modified within the scope of the claims.

What is claimed is:

1. A heat dissipation device comprising:
a heat conducting plate, defining a first through hole;
a heat dissipating fin, fixed on the heat conducting plate; and
a plurality of U-shaped heat transferring tubes;
wherein each of the plurality of heat transferring tubes comprises a first end and a second end opposite to each other, the first ends of the plurality of heat transferring tubes are connected to the heat dissipating fin, the second ends of the plurality of heat transferring tubes are arranged side by side in the first through hole, and side surfaces of the second ends of at least two heat transferring tubes are in surface contact.

2. The heat dissipation device of claim 1, wherein the second end is a cuboid, and a side of the second end away from the heat dissipating fin is flush with a side of the heat conducting plate away from the heat dissipating fin.

3. The heat dissipation device of claim 1, wherein the heat dissipating fin comprises a first side and a second side opposite to each other, the plurality of heat transferring tubes are divided into a first group and a second group, each of the first ends in the first group passes through the heat dissipating fin from the first side to the second side, and each of the first ends in the second group passes through the heat dissipating fin from the second side to the first side.

4. The heat dissipation device of claim 3, wherein the first side and the second side define two holding grooves, each of the plurality of heat transferring tubes further comprises a connecting part connecting the first end and the second end, and the connecting part is received in one of the two holding grooves.

5. The heat dissipation device of claim 3, wherein each of the first group and the second group comprises a plurality of heat transferring tubes, the first ends in each of the first group and the second group are arranged at intervals.

6. The heat dissipation device of claim 5, wherein an outer side of the second end of the first group is in surface contact with an outer side of the second end of the second group.

7. The heat dissipation device of claim 3, wherein the first group comprises three heat transferring tubes, and the second group comprises two heat transferring tubes.

8. The heat dissipation device of claim 1, wherein the first end of each of the plurality of heat transferring tubes is a cylinder.

9. The heat dissipation device of claim 1, wherein the heat conducting plate is an aluminum plate.

10. A heat dissipation device comprising:
a heat conducting plate, fixed to an electronic element and defining a first through hole;
a heat dissipating fin, positioned on the heat conducting plate; and
a plurality of U-shaped heat transferring tubes;
wherein each of the plurality of heat transferring tubes comprises a first end and a second end opposite to each other, the first ends of the plurality of heat transferring tube are fixed on the heat dissipating fin, the second ends of the plurality of heat transferring tubes are arranged side by side in the first through hole, and side surfaces of the second ends of each adjacent two heat transferring tubes are in surface contact.

11. The heat dissipation device of claim 10, wherein the second end is a cuboid, and a side of the second end away from the heat dissipating fin is flush with a side of the heat conducting plate away from the heat dissipating fin.

12. The heat dissipation device of claim 10, wherein the heat dissipating fin comprises a first side and a second side opposite to each other, the plurality of heat transferring tubes are divided into a first group and a second group, each of the first ends in the first group passes through the heat dissipating fin from the first side to the second side, and each of the first end of each heat transferring tube in the second group passes through the heat dissipating fin from the second side to the first side.

13. The heat dissipation device of claim 12, wherein the first side and the second side define two holding grooves, each of the plurality of heat transferring tubes further comprises a connecting part connecting the first end and the second end, and the connecting part is received in one of the two holding grooves

14. The heat dissipation device of claim 12, wherein each of the first group and the second group comprises a plurality of heat transferring tubes, the first ends in each of the first group and the second group are arranged at intervals.

15. The heat dissipation device of claim 14, wherein an outer side of the second end of the first group is in surface contact with an outer side of the second end of the second group.

16. The heat dissipation device of claim 12, wherein the first group comprises three heat transferring tubes, and the second group comprises two heat transferring tubes.

17. The heat dissipation device of claim 10, wherein the first end of each of the plurality of heat transferring tubes is a cylinder.

18. The heat dissipation device of claim 10, wherein the heat conducting plate is an aluminum plate.

19. A heat dissipation device assembling method, comprising:
providing a plurality of U-shaped heat transferring tubes, a heat conducting plate with a first through hole, and a heat dissipating fin with a plurality of second though holes, wherein each of the plurality of heat transferring tubes comprises a first end and a second end opposite to the first end, and side surfaces of the second ends of at least two heat transferring tubes are in surface contact;
connecting the first ends of the plurality of heat transferring tubes to the heat dissipating fin, arranging the second ends of the plurality of heat transferring tubes in the first through hole, and contacting the side surfaces of the second ends of two adjacent heat transferring tubes in surface contact; and
welding the heat conducting plate, the heat dissipating fin, and the plurality of heat transferring tubes with the first ends connected to the heat dissipating fin and the second ends in the first through hole with solder paste through a high-temperature oven.

20. The heat dissipation device assembling method of claim 19, further comprising:
performing a rolling or CNC process on a side of the second end away from the heat dissipating fin to flush with a side of the heat conducting plate away from the heat dissipating fin.
